(19) United States
(12) Patent Application Publication
(10) Pub. No.: US 2019/0043777 A1
(43) Pub. Date: Feb. 7, 2019

(54) SEMICONDUCTOR PACKAGE FOR INCREASING HEAT RADIATION EFFICIENCY

(71) Applicant: Samsung Electronics Co., Ltd., Suwon-si (KR)

(72) Inventor: Su-jung Hyung, Seoul (KR)

(21) Appl. No.: 15/870,902

(22) Filed: Jan. 13, 2018

(30) Foreign Application Priority Data
Aug. 1, 2017 (KR) 10-2017-0097816

(51) Int. Cl. H01L 23/367; H01L 25/065; H01L 25/18

(52) U.S. Cl. CPC H01L 23/3675; H01L 25/0655; H01L 2225/06589; H01L 25/18; H01L 25/0652

(57) ABSTRACT

A semiconductor package includes a thermal interface material layer located on semiconductor chips located on a surface of a substrate, and a curved surface type heat spreader on the thermal interface material layer, including a curved surface region including a curved surface in which a surface has an inflection point corresponding to a vicinity region between the semiconductor chips.

### CROSS-REFERENCE TO RELATED APPLICATION

This application claims the benefit of Korean Patent Application No. 10-2017-0097816, filed on Aug. 1, 2017, in the Korean Intellectual Property Office, the disclosure of which is incorporated herein in its entirety by reference.

### BACKGROUND

The present disclosure relates to a semiconductor package, and more particularly, to a semiconductor package for increasing a heat radiation efficiency.

As semiconductor chips (also described as semiconductor devices) become smaller and have increasingly higher degrees of integration, heat generated from the semiconductor chips should be efficiently radiated. Also, an integrated semiconductor package wherein more than two semiconductor chips are integrated to increase a capacity or functionality typically needs an increase in a radiation efficiency of heat generated from the semiconductor chips. As used herein, a semiconductor device may refer broadly to a semiconductor chip, or a semiconductor package that includes one or more semiconductor chips. In addition, a semiconductor package includes a package substrate and one or more chips mounted thereon, and also includes a molding layer that covers spaces between the semiconductor chips and/or the package substrate and/or tops of the semiconductor chips. As discussed further below, a package may also include a heat spreader element, for example, that continuously covers all of the chips included in the package.

### SUMMARY

The embodiments disclosed herein provide a semiconductor package for increasing a heat radiation efficiency.

According to an aspect of the inventive concept, a semiconductor package includes a package substrate having a front surface and a rear surface; a plurality of semiconductor chips including at least a first semiconductor chip and a second semiconductor chip separately located to be horizontally adjacent to each other on the front surface of the package substrate; a thermal interface material layer located on the plurality of semiconductor chips; and a curved surface type heat spreader located on the thermal interface material layer, wherein the thermal interface material layer is between the curved surface type heat spreader and the plurality of semiconductor chips, and wherein a surface of the curved surface type heat spreader has a curved surface region comprising a curved surface having an inflection point corresponding to a vicinity region between the first semiconductor chip and the second semiconductor chip.

According to another aspect of the inventive concept, a semiconductor package includes a package substrate; a plurality of semiconductor chips including a first semiconductor chip horizontally adjacent to a second semiconductor chip on the substrate; a thermal interface material layer located on and entirely attached on the semiconductor chips; and a curved surface type heat spreader, wherein the curved surface type heat spreader contacts an entire upper surface of the thermal interface material layer, and has a contact face that contacts the upper surface of the thermal interface material layer includes a curved surface region including a curved surface having an inflection point corresponding to a vicinity region between the first semiconductor chip and the second semiconductor chip.

According to another aspect of the inventive concept, a semiconductor package includes a package substrate having a front surface and a rear surface; a plurality of semiconductor chips including at least a first semiconductor chip and a second semiconductor chip separately located to be horizontally adjacent to each other on the front surface of the package substrate; a thermal interface material layer located on the plurality of semiconductor chips and located on a molding layer formed between the first semiconductor chip and the second semiconductor chip; and a curved surface type heat spreader located on the thermal interface material layer, wherein the thermal interface material layer is between the curved surface type heat spreader and the plurality of semiconductor chips, and is between the curved surface type heat spreader and the molding layer, and wherein a surface of the curved surface type heat spreader has a curved surface region comprising a curved surface having an inflection point corresponding to a vicinity region between the first semiconductor chip and the second semiconductor chip where the molding layer is located.

A semiconductor package according to an aspect of the present inventive concept includes a thermal interface material layer located on semiconductor chips loaded on a front surface of a substrate, and a curved surface type heat spreader on the thermal interface material layer, wherein a surface includes a curved surface region including a curved surface having an inflection point corresponding to a vicinity region between the semiconductor chips.

Accordingly, the semiconductor package according to some embodiments is not provided with an air layer between the thermal interface material layer and the curved surface type heat spreader, and the thermal interface material layer on the semiconductor chips fills the entire thickness between the semiconductor chips and the curved surface type heat spreader on a contact surface, thus, a heat radiation efficiency may increase.

### BRIEF DESCRIPTION OF THE DRAWINGS

Embodiments of the inventive concept will be more clearly understood from the following detailed description taken in conjunction with the accompanying drawings in which:

FIG. 1 is a top-plan view illustrating a semiconductor package according to an aspect of the present inventive concept;

FIG. 2 is an example cross-sectional view of the semiconductor package cut along a line II-II of FIG. 1, according to one embodiment;

FIG. 3 is an example rear view of a curved surface type heat spreader of FIG. 1, according to one embodiment;

FIG. 4 is an example detailed cross-sectional view illustrating the curved surface type heat spreader of FIG. 1, according to one embodiment;

FIG. 5 is a diagram illustrating a heat radiation property of a semiconductor package according to certain embodiments;

FIG. 6 is an example cross-sectional view of a semiconductor package of a comparative embodiment to describe a heat radiation efficiency of the semiconductor package of FIG. 2;

FIG. 7 is a cross-sectional view of a semiconductor package according to an aspect of the present inventive concept;

FIG. 8 is an example detailed cross-sectional view of a curved surface type heat spreader of FIG. 7, according to one embodiment;

FIG. 9 is a cross-sectional view of a semiconductor package according to an aspect of the present inventive concept;

FIG. 10 is an example detailed cross-sectional view of a curved surface type heat spreader of FIG. 9, according to one embodiment;

FIG. 11 is a cross-sectional view of a semiconductor package according to an aspect of the present inventive concept;

FIG. 12 is an example detailed cross-sectional view of a curved surface type heat spreader of FIG. 11, according to one embodiment;

FIG. 13 is a cross-sectional view of a semiconductor package according to an aspect of the present inventive concept;

FIG. 14 is an example cross-sectional view of the semiconductor package cut along a line XVI-XVI of FIG. 13, according to one embodiment;

FIGS. 15 and 16 are cross-sectional views respectively illustrating a semiconductor package according to an aspect of the present inventive concept.

### DETAILED DESCRIPTION

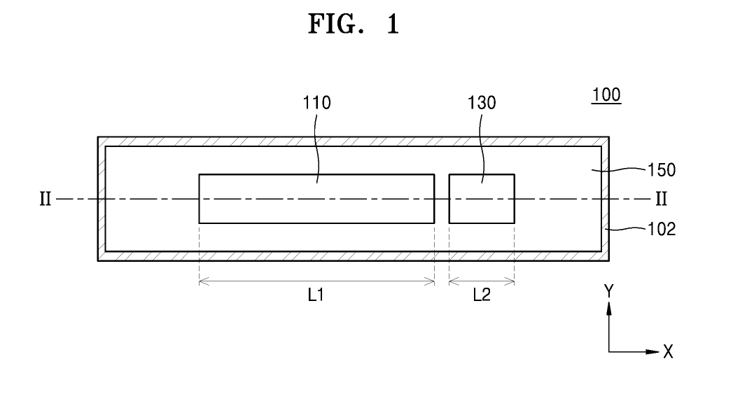

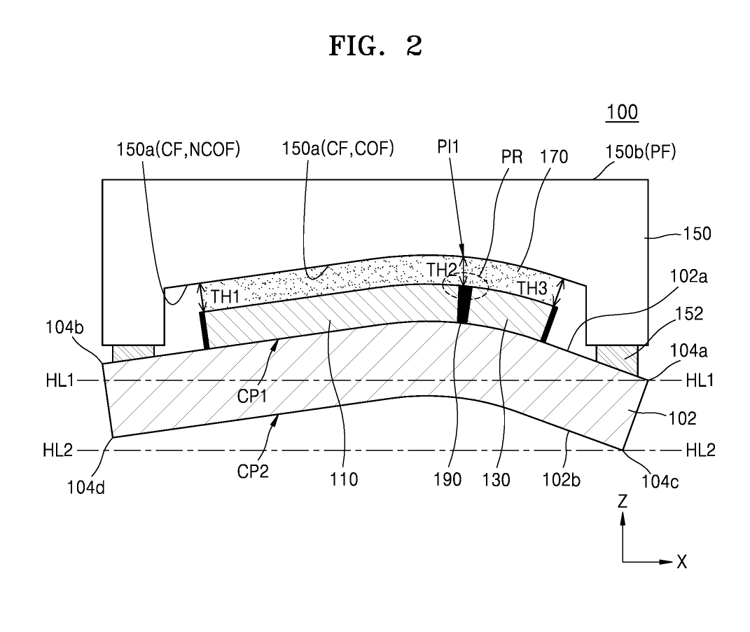

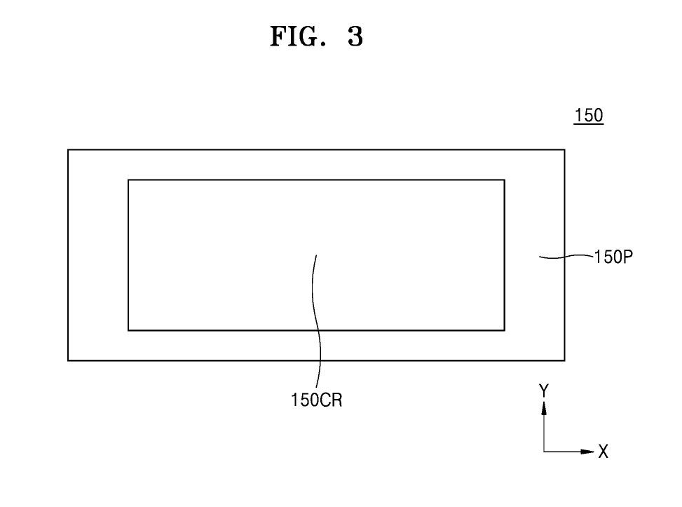

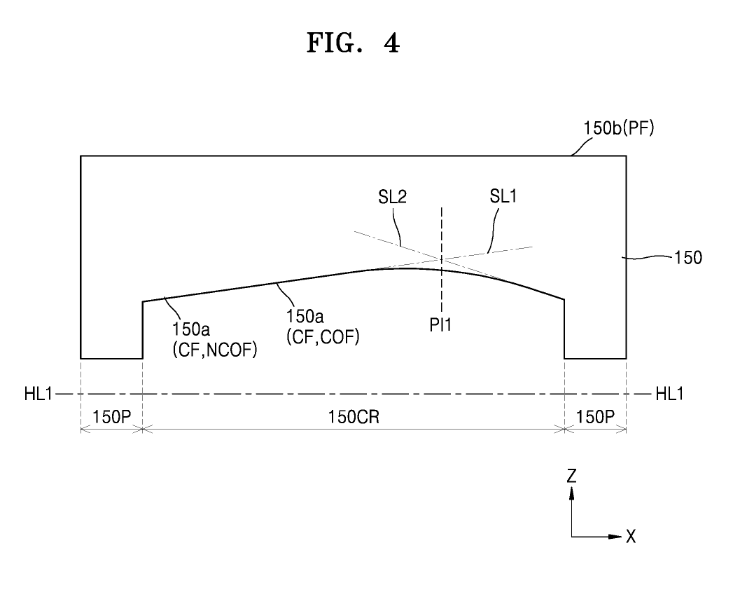

FIG. 1 is a top-plan view of a semiconductor package 100 according to an aspect of the present inventive concept, FIG. 2 is an example top-plan view of the semiconductor package 100 cut along a line II-II of FIG. 1, FIG. 3 is an example rear view of a curved surface type heat spreader of FIG. 1, and FIG. 4 is an example detailed cross-sectional view illustrating the curved surface type heat spreader of FIG. 1.

The semiconductor package 100 may include a plurality of semiconductor chips 110 and 130 separately located on the substrate 102 to be horizontally adjacent to each other. The semiconductor chips 110 and 130 may be located separately in an X direction. In FIGS. 1 through 4, the X direction or a Y direction may be parallel to edges the substrate 102 from a top-plan view, and a Z direction may be a vertical direction with respect to the substrate 102.

The substrate 102 may be a printed circuit substrate (PCB). The substrate 102 may include a front surface 102a and a rear surface 102b (also described as a first, or top, surface 102a, and a second or bottom surface 102b). External connection terminals that are electrically connected to an external apparatus may be formed on the rear surface 102b of the substrate 102. The external connection terminal may be made, for example, from solder materials such as a solder ball, a solder bump, solder paste, or may be made of metal having a form of a sphere, a mesa or a pin. For convenience, the external connection terminal is omitted in FIG. 2.

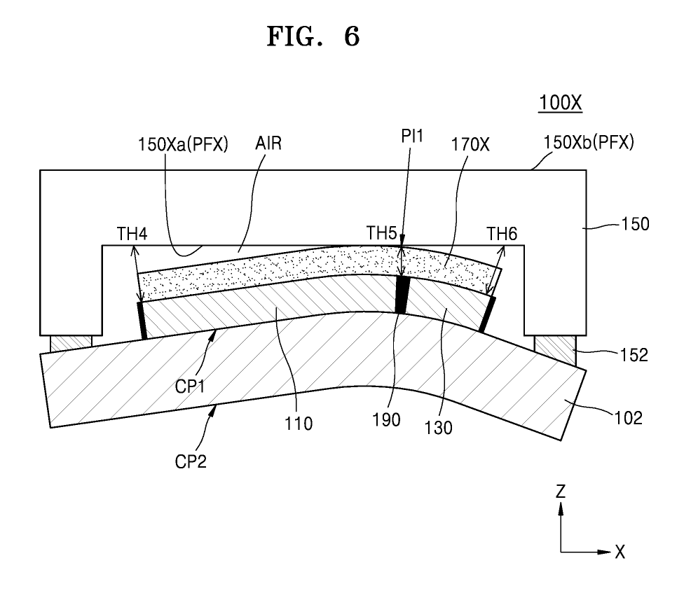

The substrate may be a bulged type having the front surface 102a and the rear surface 102b bulging upward (e.g., in relation to a horizontal line below the substrate 102). The substrate 102 may be curved in a manufacturing process of the semiconductor package 100 and have curved faces CP1 and CP2. The substrate 102 may include the curved faces CP1 and CP2 curved with respect to the hypothetical horizontal levels HL1 and HL2 with respect to the front surface 102a or the rear surface 102b. The hypothetical horizontal levels HL1 and HL2 may indicate hypothetical levels horizontal with respect to the front surface 102a or the rear surface 102b of the substrate 102 prior to being curved during the manufacturing process. The amount of curvature is exaggerated in the figures for demonstration purposes, and in practice may be large enough to cause an air gap between a thermal interface material layer and a flat surface of a heat spreader such as shown in comparative example of FIG. 6 (see explanation below), but small enough such that the external connection terminals are still able to all electrically and physically connect to respective terminals on an external device.

The curved faces CP1 and CP2 may include a curved face CP1 and another curved face CP2 respectively formed on the front surface 102a and the rear surface 102b of the substrate 102. There may not be a hypothetical horizontal level HL1 between two ends 104a and 104b of the front surface 102a of the substrate 102. There may not be another hypothetical horizontal level HL2 between two ends 104c and 104d of the rear surface 102b of the substrate 102. Accordingly, the curved faces CP1 and CP2 may be curved with respect to the hypothetical horizontal levels HL1 and HL2 in an irregular shape, instead of a regular shape. For example, prior to a manufacturing process that causes the substrate 102 to curve or warp, the bottom surface of the substrate 102 may be flat and horizontal, such as along line HL2, and the top surface of the substrate 102 may be flat and horizontal, such as along line HL1. However, after the manufacturing process and after substrate 102 becomes curved, both the top and bottom surfaces may become curved. Furthermore, in some embodiments, after external connection terminals are added, the resulting semiconductor package 100 may have one end (e.g., 104c) that is lower than a second end (e.g., 104d), such that those two ends do not fall along a horizontal line, such as HL2. As shown for example in FIG. 2, the substrate may have a bent shape that is not symmetrical.

A plurality of semiconductor chips (e.g., two semiconductor chips such as 110 and 130) may be mounted on the curved face CP1 of the front surface 102a of the substrate 102. The semiconductor chips 110 and 130 may be located on the curved face CP1 of the substrate 102 in the X direction, which is a horizontal direction. The semiconductor chips 110 and 130 may be horizontally adjacent to each other. As the semiconductor chips 110 and 130 are located on the curved face CP1 of the substrate, a height of the semiconductor chip 110 may be different from a height of the semiconductor chip 130 from a hypothetic horizontal level HL1 in a vertical direction, which is the Z direction.

Molding layers 190 may be formed respectively between the semiconductor chips 110 and 130 and on one side of each of the semiconductor chips 110 and 130. The molding layers 190 may include an epoxy molding compound (EMC). The molding layers 190 may be formed for protection of the semiconductor chips 110 and 130. The molding layers 190 may be thicker or thinner than the semiconductor chips 110 and 130. The molding layers 190 may have various widths as needed.

The semiconductor chips 110 and 130 may include a first semiconductor chip 110 and a second semiconductor chip 130. Each of the first semiconductor chip 110 and the second semiconductor chip 130 may be a single semiconductor chip. The first semiconductor chip 110 may be larger than the semiconductor chip 130. For example, in FIG. 1, a length L1 of the first semiconductor chip 110 is illustrated to be longer than a length L2 of the second semiconductor chip 130 in the X direction, however, it is not limited thereto and the first semiconductor chip 110 may also be longer than the second semiconductor chip 130 in the Y direction.

The first semiconductor chip 110 may be a logic chip or a control chip. The second semiconductor chip 130 may be a memory chip. The first semiconductor chip 110 may be a microcontroller or a microprocessor used for driving the semiconductor package 100 or controlling the second semiconductor chip 130. The second semiconductor chip 130 may be flash memory, Dynamic Random Access Memory (DRAM), Static Random Access Memory (SRAM), Erasable Programmable Read Only Memory (EPROM), Electrically Erasable Programmable Read Only Memory (EEPROM), Flash EEPROM, Magnetic RAM (MRAM), phase change RAM (PRAM), Resistive RAM (RRAM).

The semiconductor package 100 may include a thermal interface material layer (TIM layer) 170 that is entirely located on surfaces of the semiconductor chips 110 and 130. The TIM layer 170 may be made of a material having a heat conductivity better than a heat conductivity of air. Note that the term “air” is used herein to refer not only to atmospheric air, but also may refer to the gasses that would naturally fill in gaps in material during a manufacturing process of a semiconductor package. The TIM layer 170 may be installed so that heat may be easily radiated to the curved surface type heat spreader 150 mounted thereon. The TIM layer 170 may include, for example, an adhesive having a low or high elasticity. The TIM layer 170 may be a hardened material that is hardened during a manufacturing process.

The TIM layer 170 before hardening may have viscosity. The TIM layer 170 may include a monomer resin or a polymer resin having particles with heat conduction quality. For example, the TIM layer 170 may include aluminum oxide (AlO), zinc oxide (ZnO), sclerogenic resin or a combination thereof.

The TIM layer 170 may be entirely attached on upper surfaces of the semiconductor chips 110 and 130. In some embodiments, adhesion thicknesses TH1 and TH3 of the TIM layer 170 on edges of the semiconductor chips 110 and 130 and an adhesion thickness TH 2 of the TIM layer 170 on a portion between the semiconductor chips 110 and 130 may be the same. Terms such as “same,” “equal,” “planar,” “coplanar,” or “uniform,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes. The TIM layer 170 may easily radiate heat generated from the semiconductor chips 110 and 130 when attached on the curved surface type heat spreader 150 on the semiconductor chips 110 and 130 in a uniform thickness.

The semiconductor package 100 may include a curved surface type heat spreader 150 located on the TIM layer 170. The curved surface type heat spreader 150 may include a material with high heat conductivity. For example, the curved surface type heat spreader 150 may include a material including copper (Cu), iron (Fe), nickel (Ni), cobalt (Co), tungsten (W), chrome (Cr), silver (Ag), gold (Au), platinum (Pt), tin (Sn), aluminum (Al), magnesium (Mg), silicon (Si), zinc (Zn) or a combination thereof. The curved surface type heat spreader 150 may also be described as a heat sink, or a heat dissipation component, and is included specifically for the transfer of heat without transferring voltage, current, or signals.

Referring to FIGS. 2 and 4, the curved surface type heat spreader 150 may include a surface 150a having a middle portion recessed inward (e.g., with respect to a flat top of the curved surface type heat spreader 150); and another surface 150b (e.g., the top surface, which may be flat) opposite the surface 150a. As illustrated in FIGS. 2 through 4, the curved surface type heat spreader 150 may include a curved surface region 150CR including a curved surface having an inflection point PI1 provided correspondingly to a vicinity region PR between the semiconductor chips 110 and 130 on the surface 150a recessed inward. The vicinity region PR may be described as a gap region between the semiconductor chips 110 and 130. The surface 150a may be a rear surface.

As illustrated in FIG. 4, the inflection point PI1 may be a point at which slopes SL1 and SL2 are changed from positive values to negative values with respect to the front surfaces 102a of the substrate 102. A slope SL1 may have a positive value, and another slope SL2 may have a negative value. Absolute values of the slope SL1 and the other slope SL2 may be same, but may also be different. In the curved surface type heat spreader 150, a part on which the inflection point PI1 is located may be more bulged upward. The other surface 150b of the curved surface type heat spreader 150 may be a flat surface. The other surface 150b may be a top surface of the curved surface type heat spreader 150. The other surface 150b may be horizontal or may be slanted, depending on the orientation of the remainder of the semiconductor package 100.

The substrate 102 may have the curved faces CP1 and CP2 to correspond to the curved surface CF in the curved surface region 150CR of the curved surface type heat spreader 150. When the curved surface type heat spreader 150 is a bulged type having the surface 150a bulging upward, the substrate 102 may be a bulged type having the front surface 102a or the rear surface 102b bulging upward.

On the surface 150a of the curved surface region 150CR, as illustrated in FIGS. 2 and 4, a contact face COF that contacts the TIM layer 170 and a non-contact face NCOF that does not contact the TIM layer 170 may be provided. As described herein, “contact” refers to touching, or a direct connection. On surfaces of the semiconductor chips 110 and 130, an air layer may not be formed between the TIM layer 170 and the curved surface type heat spreader 150 (e.g., in a direction perpendicular to top surfaces of the semiconductor chips 110 and 130). In one embodiment, the TIM layer 170 on the semiconductor chips 110 and 130 has a uniform thickness on the contact face COF, and as a result, heat radiation efficiency may increase.

The curved surface type heat spreader 150 may include supporting units 150P which may be attached on and supported by the substrate 102 through adhesion layers 152 around the curved surface region 150CR, for example, on two ends of the curved surface region 150CR. The curvature of the curved surface region 150CR is formed such that it matches the curvature of the substrate 102. Compared to the curved surface region 150CR, the supporting units 150P may be projections protruding in a Z direction. The adhesion layers 152 may be formed by using epoxy resins having the form of liquid or a film.

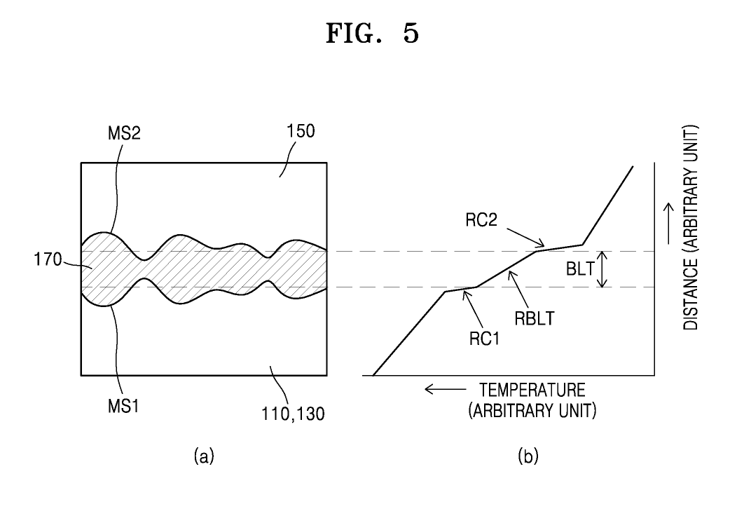

FIG. 5 is a diagram used for describing a heat radiation property of the semiconductor package according to certain embodiments.

In one embodiment, FIG. 5 is an exaggerated diagram used for describing the property of heat radiation property through the TIM layer 170 in the semiconductor package (100 of FIGS. 1 through 4) of the present inventive concept.

The (a) part in FIG. 5 is a diagram illustrating the TIM layer 170 completely filled between the semiconductor chips 110 and 130 with an uneven fine surface MS1 and the curved surface type heat spreader 150 with another uneven fine surface MS2. In one embodiment, an upper surface and a lower surface of the TIM layer 170 are entirely attached respectively to the semiconductor chips 110 and 130 and the curved surface type heat spreader 150.

The (b) part in FIG. 5 is a graph illustrating a heat resistance curve of a heat transfer process from the semiconductor chips 110 and 130 with the uneven fine surface MS1 via the TIM layer 170 to the curved surface type heat spreader 150 with the other uneven fine surface MS2 in the semiconductor package of the present disclosure (100 in FIGS. 1 through 4).

A heat resistance may indicate a property that interrupts heat conduction. When heat is transferred through the TIM layer 170 of the semiconductor package (100 of FIGS. 1 through 4), as illustrated in (b) of FIG. 5, the heat resistance may be a sum of a first heat resistant constituent RC1 between the semiconductor chips 110 and 130 and the TIM layer 170, a second heat resistant constituent RBLT generated by the TIM layer 170, and a third heat resistant constituent RC2 between the TIM layer 170 and the curved surface type heat spreader 150.

Heat resistance of the first heat resistant constituent RC1 and the third heat resistant constituent RC2 may decrease when there is no air layer provided between the semiconductor chips 110 and 130 and the TIM layer 170. The second heat resistant constituent RBLT may have a low heat resistance when the TIM layer 170 has a thin adhesion thickness BLT or a low heat conductivity.

As described above, the semiconductor package (100 of FIGS. 1 through 4) may have a low heat resistance as the TIM layer 170 is entirely attached on the semiconductor chips 110 and 130 and the curved surface type heat spreader 150 and there is no air layer provided.

Accordingly, as described above, the semiconductor package (100 of FIGS. 1 through 4) may have a thin adhesion thickness BLT. For example, the thickness BLT of the TIM layer 170 may be several to dozens of micrometers. As a result, the semiconductor package (100 of FIGS. 1 through 4) may have a low heat resistance and improve a heat radiation efficiency.

FIG. 6 is a cross-sectional view of a semiconductor package of a comparative embodiment used for describing a heat radiation efficiency of the semiconductor package of FIG. 2.

In the following description, in FIGS. 2 and 6, like reference numerals are used to represent same components. In FIG. 6, explanations overlapping with those of FIG. 2 are briefly described or omitted. A semiconductor package 100X of the comparative embodiment may include the plurality of semiconductor chips 110 and 130 located on the substrate 102, a TIM layer 170X located on the plurality of semiconductor chips 110 and 130, and a heat spreader 150X located on the TIM layer 170X.

The heat spreader 150X may include a surface 150Xa facing the TIM layer 170X and another surface 150Xb opposite the surface 150Xa. Both the surface 150Xa and the other surface 150Xb may have flat faces PFX. Thicknesses of the TIM layer 170X and air gaps on edges of the semiconductor chips 110 and 130 may be different from an thickness TH5 of the TIM layer 170X (with or without air gaps) on a portion between the semiconductor chips 110 and 130. Due to an air layer, the thicknesses TH4 and TH6 of the TIM layer 170X and air gaps on edges of the semiconductor chips 110 and 130 may be thicker than the thickness TH5 of the TIM layer 170 (with or without air gaps) on the portion between the semiconductor chips 110 and 130.

As described above, compared to the semiconductor package 100, the TIM layer 170X in the semiconductor package 100 of the comparative embodiment is not entirely attached on the semiconductor chips 110 and 130 and the curved surface type heat spreader 150.

Compared to the semiconductor package 100 of FIGS. 1 through 4, the thicknesses TH4 to TH6 are not uniform in the semiconductor package 100X of the comparative embodiment, and the thicknesses TH4 and TH6 on the edges of the semiconductor chips 110 and 130 are thicker. As shown in FIG. 6, in the semiconductor package 100X of the comparative embodiment, the air layer AIR is formed between the semiconductor chips 110 and 130 and the heat spreader 150X.

As a result, the semiconductor package 100X of the comparative embodiment has a heat resistance higher than a heat resistance of the semiconductor package 100 of FIGS. 1 through 4, therefore, a heat radiation efficiency may decrease.

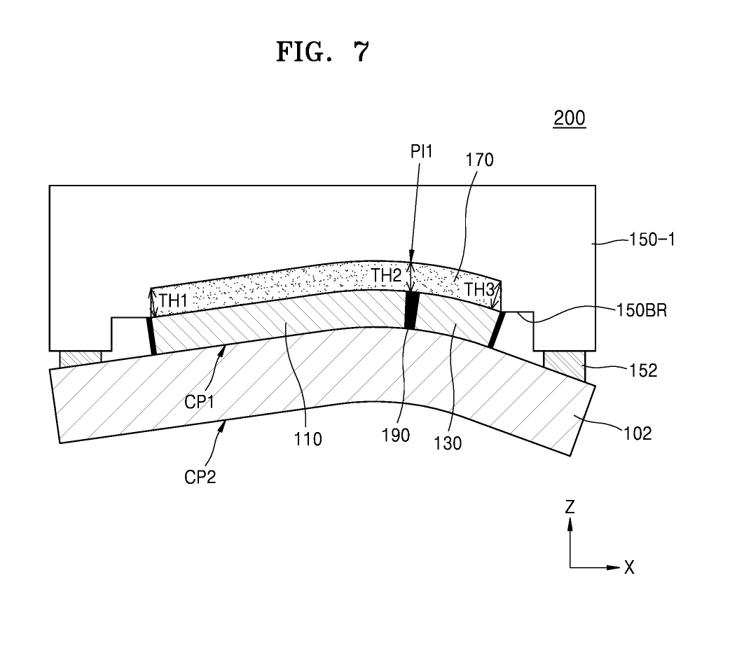

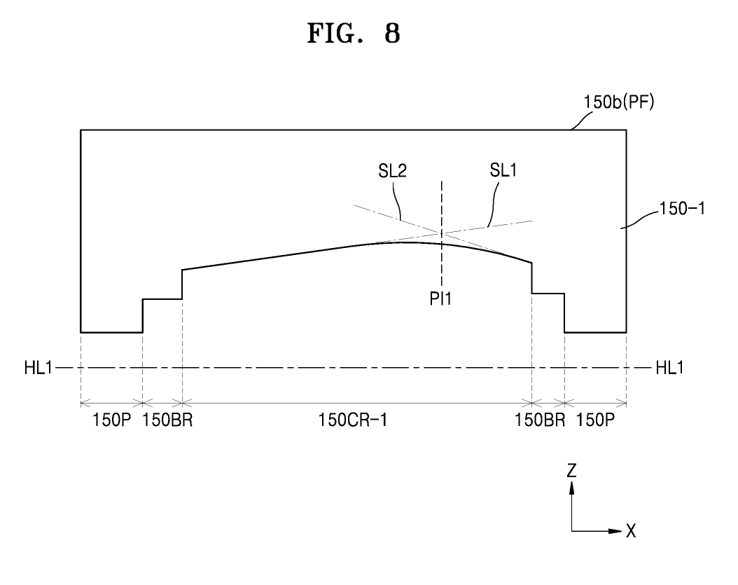

FIG. 7 is a cross-sectional view illustrating a semiconductor package according to an aspect of the present inventive concept, and FIG. 8 is an example detailed cross-sectional view of a curved surface type heat spreader in FIG. 7.

In one embodiment, a semiconductor package 200 in FIGS. 7 and 8 is almost the same as the semiconductor package 100 in FIGS. 1 through 4 except for a curved surface type heat spreader 150-1 including height difference regions 150BR. In FIGS. 7 and 8, reference numbers the same as those of FIGS. 1 through 4 are used to represent same components. In FIGS. 7 and 8, overlapping explanations with those in FIGS. 1 through 4 are briefly described or omitted.

The semiconductor package 200 may include the plurality of semiconductor chips 110 and 130 located on the substrate 102, the TIM layer 170 located on the semiconductor chips 110 and 130, and a curved surface type heat spreader 150-1 located on the TIM layer 170.

The curved surface type heat spreader 150-1 may further include height difference regions 150BR corresponding to two ends of the semiconductor chips 110 and 130 and being connected to the curved surface region 150CR-1. For example, the height difference regions may have step structures including a step (150BR) between the curved surface region 150CR-1 and the supporting units 150P. Due to the height difference regions 150BR, the curved surface region 150CR-1 may have a region smaller than the curved surface region 150CR of FIG. 4.

Due to the height difference regions 150BR, the TIM layer 170 may not be formed at an external region of the semiconductor chips 110 and 130. Due to the height difference regions 150BR, the TIM layer 170 may be properly formed on an entire upper surfaces of the semiconductor chips 110 and 130 without a loss during a manufacturing process.

Accordingly, the adhesion thicknesses TH1 and TH3 of the TIM layer 170 on the edges of the semiconductor chips 110 and 130 may be the same as the adhesion thickness TH2 of the TIM layer 170 on the portion between the semiconductor chips 110 and 130. When the TIM layer 170 is attached on the curved surfaces type heat spreader 150-1 in a uniform thickness on the semiconductor chips 110 and 130, heat generated from the semiconductor chips 110 and 130 may be easily released.

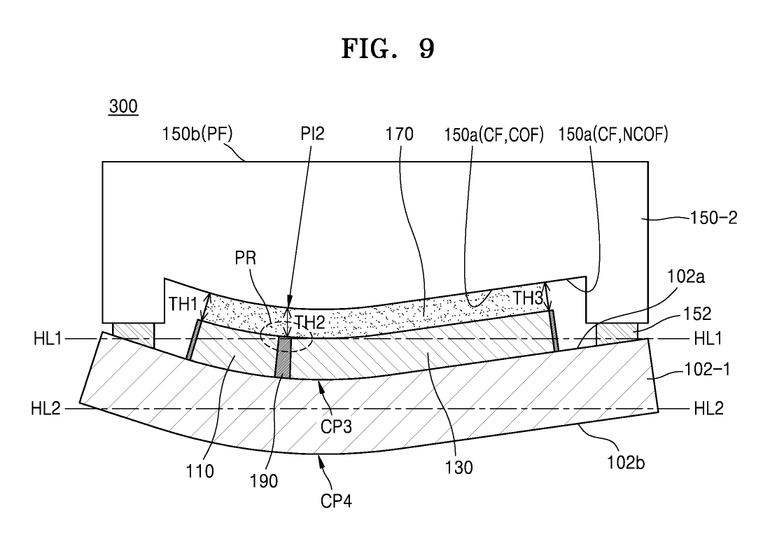

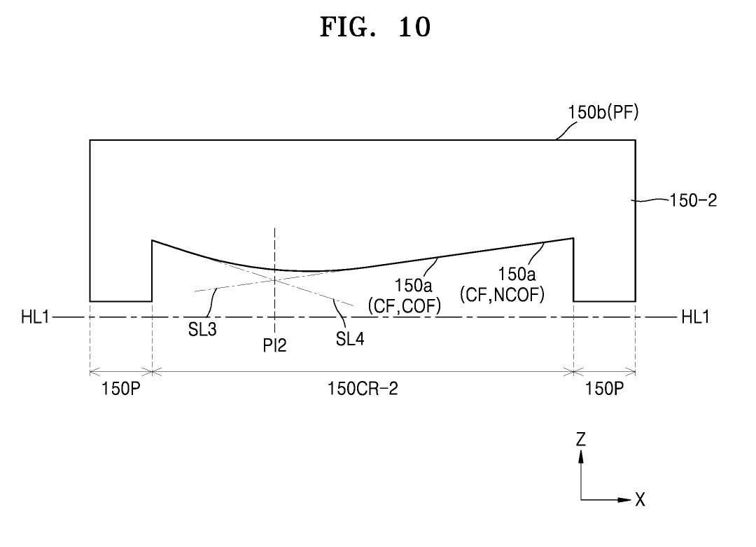

FIG. 9 is a cross-sectional view illustrating a semiconductor package according to an aspect of the present inventive concept, and FIG. 10 is an example detailed cross-sectional view of a curved surface type heat spreader in FIG. 9.

In one embodiment, a semiconductor package 300 in FIGS. 9 and 10 is almost the same as the semiconductor package 100 in FIGS. 1 through 4 except for a substrate 102-1 and a curved surface type heat spreader 150-2. In FIGS. 9 and 10, reference numerals the same as those of FIGS. 1 through 4 are used to represent same components. In FIGS. 9 and 10, explanations overlapping with those of FIGS. 1 through 4 are briefly described or omitted.

The semiconductor package 300 may include the plurality of semiconductor chips 110 and 130 located on a substrate 102-1, the TIM layer 170 located on the semiconductor chips 110 and 130 and a curved surface type heat spreader 150-2 located on the TIM layer 170.

The substrate 102-1 may be curved during a manufacturing process of the semiconductor package 300 and have curved faces CP3 and CP4. The substrate 102-1 may be formed in a bulged type having a front surface 102a and a rear surface 102b bulging downward. The substrate 102-1 may be provided with the curved faces CP3 and CP4 curved with respect to the hypothetical horizontal levels HL1 and HL2 with respect to the front surface 102a or the rear surface 102b.

The curved surface type heat spreader 150-2 may include a surface 150a having a middle portion recessed inward in a bulging manner; and another surface 150b opposite the surface 150a. The curved surface type heat spreader 150-2 may be provided with a curved surface region 150CR-2 including a curved surface CF having an inflection point PI2 provided on the recessed surface 150a corresponding to a vicinity region PR between the semiconductor chips 110 and 130. The surface 150a may be a rear surface. The inflection point PI2 may be a point at which slopes SL3 and SL4 of the curved surface CF in the curved surface region 150CR-2 are changed from a negative value to a positive value with respect to the front surface 102a or the rear surface 102b of the substrate 102-1. A slope SL3 may have a negative value, and another lope SL4 may have a positive value.

Absolute values of the slope SL3 and the other slope SL4 may be same, but may also be different. In the curved surface type heat spreader 150-2, a portion at which the inflection point PI2 is located may be more bulged. The other surface 150b of the curved surface type heat spreader 150-2 may be a flat surface PF. The other surface 150b may be a surface of the curved surface type heat spreader 150-2.

The substrate 102-1 may have the curved faces CP3 and CP4 corresponding to the curved surface CF of the curved surface region 150CR-2 in the curved surface type heat spreader 150-2. The curved surface type heat spreader 150-2 may be a bulged type having the surface bulging downward, and the substrate 102-1 may be a bulged type having the front surface 102a or the rear surface 102b bulging downward. A contact surface COF which contacts the TIM layer 170 and a non-contact face NCOF which does not contact the TIM layer 170 may be provided on the surface 150a of the curved surface region 150CR-2.

On surfaces of the semiconductor chips 110 and 130, an air layer may not be formed between the TIM layer 170 and the curved surface type heat spreader 150-2. A thickness of the TIM layer 170 on the semiconductor chips 110 and 130 may be entirely the same on the contact surface COF, thus, a heat radiation efficiency may increase.

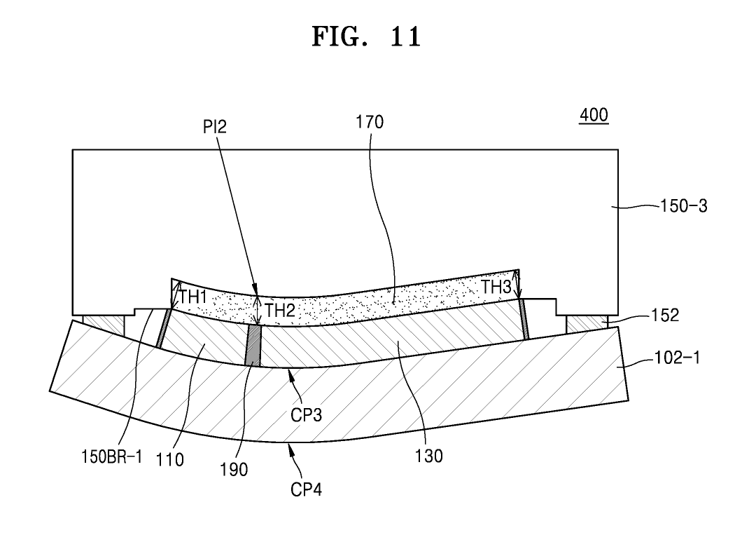

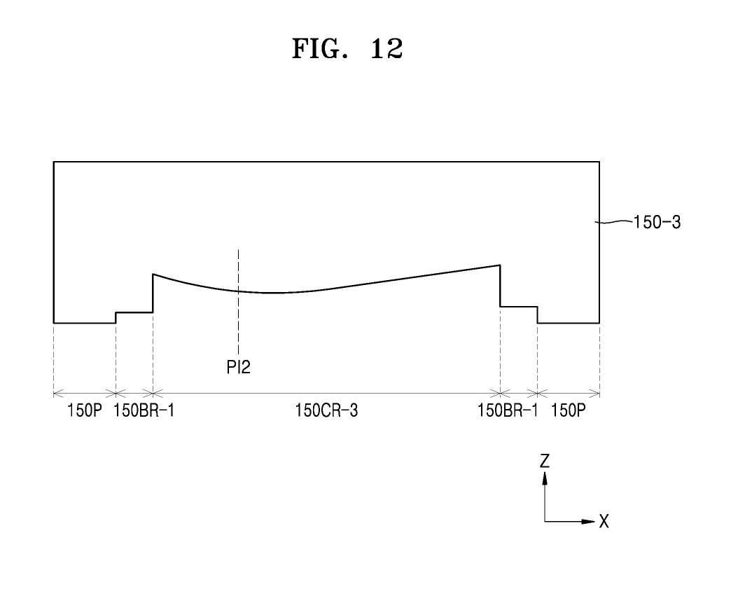

FIG. 11 is a cross-sectional view illustrating a semiconductor package according to an aspect of the present inventive concept, FIG. 12 is an example detailed cross-sectional view of a curved surface type heat spreader in FIG. 11.

In one embodiment, a semiconductor package 400 in FIGS. 11 and 12 is almost the same as the semiconductor package 100 in FIGS. 1 through 4 except for the substrate 102-1 and a curved surface type heat spreader 140-3. The semiconductor package 400 in FIGS. 11 and 12 are almost the same as the semiconductor package 300 in FIGS. 9 and 10 except for a curved surface type heat spreader 150-3 including height difference regions 150BR-1.

In FIGS. 11 and 12, reference numerals the same as those of FIGS. 1 through 4 and FIGS. 9 and 10 are used to represent same components. In FIGS. 11 and 12, explanations overlapping with those of FIGS. 1 through 4 and FIGS. 9 and 10 are briefly described or omitted.

The semiconductor package 400 may include the plurality of semiconductor chips 110 and 130 located on the substrate 102-1, the TIM layer 170 located on the semiconductor chips 110 and 130, and a curved surface type heat spreader 150-3 located on the TIM layer 170.

The substrate 102-1 may be bent during a manufacturing process of the semiconductor package 400 and have the curved faces CP3 and CP4. The substrate 102-1 may have the curved surfaces CP3 and CP4 to correspond to a curved surface region 150CR-3 of the curved surface type heat spreader 150-3.

The curved surface type heat spreader 150-3 may further include height difference regions 150BR-1 corresponding to left and right ends of the semiconductor chips 110 and 130 and being connected to a curved surface region 150CR-3. Due to the height difference regions 150BR-1, the curved surface region 150CR-3 may have a region smaller than the curved surface region 150CR-2 in FIG. 10.

Due to the height difference regions 150BR-1, the TIM layer 170 may not be formed at an external region of the semiconductor chips 110 and 130. Due to the height difference regions 150BR-1, the TIM layer 170 may be formed on the entire upper surface of the semiconductor chips 110 and 130 without a loss during a manufacturing process.

Accordingly, the adhesion thicknesses TH1 and TH3 of the TIM layer 170 on edges of the semiconductor chips 110 and 130 may be the same as the adhesion thickness TH2 of the TIM layer 170 on a portion between the semiconductor chips 110 and 130. When the TIM layer 170 on the semiconductor chips 110 and 130 are attached on the curved surface type heat spreader 150-3 in a uniform thickness, heat generated from the semiconductor chips 110 and 130 may be easily radiated.

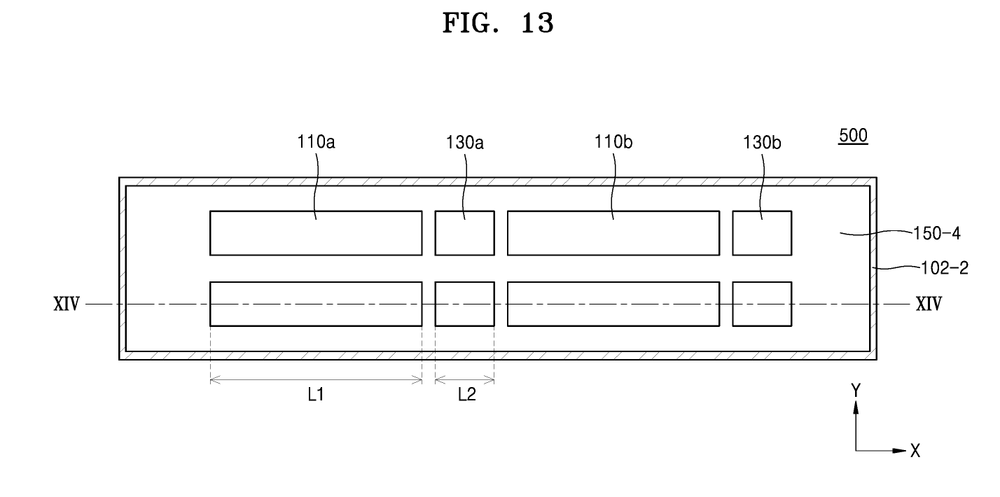

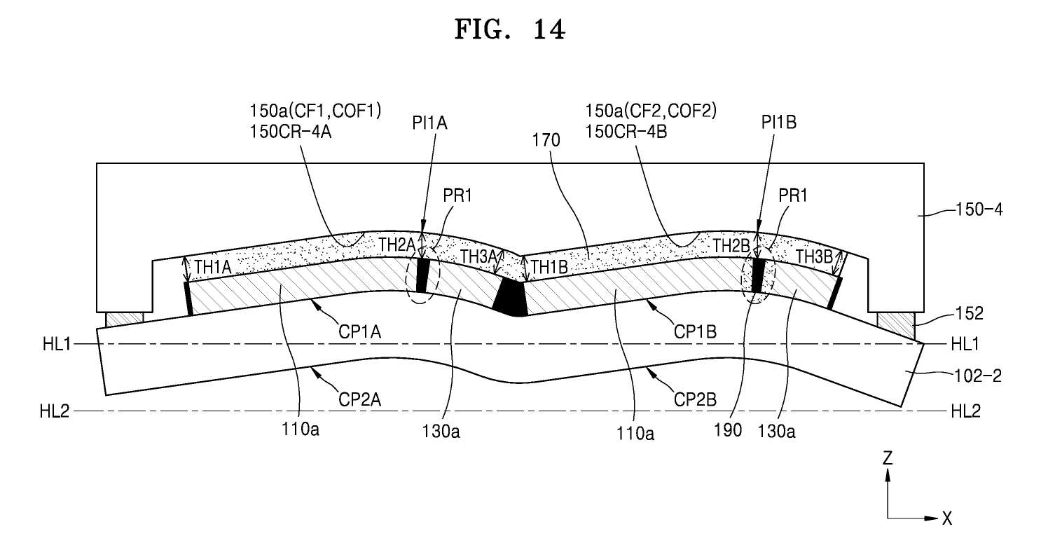

FIG. 13 is a top-plan view illustrating a semiconductor package 500 according to an aspect of the present inventive concept, and FIG. 14 is an example cross-sectional view of the semiconductor package 500 cut along a line XIV-XIV of FIG. 13.

In one embodiment, the semiconductor package 500 in FIGS. 13 and 14 is almost the same as the semiconductor package 100 except for four semiconductor chips 110a and 110b and 130a and 130b mounted on a substrate 102-2. In FIGS. 13 and 14, reference numerals the same as those of FIGS. 1 through 4 are used to represent same components. In FIGS. 13 and 14, explanations overlapping with those of FIGS. 1 through 4 are briefly described or omitted.

A semiconductor package 500 may include a plurality of semiconductor chips (e.g., four semiconductor chips 110a and 110b and 130a and 130b), the TIM layer 170 located on the semiconductor chips 110a and 110b and 130a and 130b, and a curved surface type heat spreader 150-4 located on the TIM layer 170.

The substrate 102-2 may be bent during a manufacturing process of the semiconductor package 500 and have curved faces CP1A and CP1B and CP2A and CP2B. Each pair of the curved faces CP1A and CP1B and CP2A and CP2B may be respectively formed on each of the front surface 102a and the rear surface 102b of the substrate 102-2. The curved faces CP1A and CP1B and CP2A and CP2B may be curved in an irregular shape, instead of a regular shape.

A plurality of semiconductor chips (e.g., four semiconductor chips 110a and 110b and 130a and 130b) may be loaded on the curved faces CP1A and CP1B and CP2A and CP2B of the front surface 102a of the substrate 102-2. The semiconductor chips 110a and 110b may be chips the same as the first semiconductor chip 110 described above, and the semiconductor chips 130a and 130b may be chips the same as the second semiconductor chip 130 described above.

The semiconductor chips 110a and 110b and 130a and 130b are separately located in a horizontal direction on the curved faces CP1A and CP1B and CP2A and CP2B of the substrate 102-2. As the semiconductor chips 110a and 110b and 130a and 130b are located on the curved faces CP1A and CP1B and CP2A and CP2B of the substrate 102, heights of the semiconductor chips 110a and 110b and 130a and 130b in the vertical direction, for example, the Z direction, may be different.

The TIM layer 170 may be entirely attached on upper surfaces of the semiconductor chips 110a and 110b and 130a and 130b. Adhesion thicknesses TH1A and TH3A and TH1B and TH3B of the TIM layer on the edges of the semiconductor chips 110a and 110b and 130a and 130b may be the same as adhesion thicknesses TH2A and TH2B of the TIM layer 170 on portions between the semiconductor chips 110a and 110b and 130a and 130b. The TIM layer 170 may easily radiate heat generated from the semiconductor chips 110a and 110b and 130a and 130b when attached on the curved surface type heat spreader 150-4 in a uniform thickness on the semiconductor chips 110a and 110b and 130a and 130b.

In the curved surface type heat spreader 150-4, curved surface regions 150CR-4A and 150CR-4B including curved faces CF1 and CF3 including a plurality of inflection points PI1A and PH1B provided on the surface 150a recessed inward correspondingly to vicinity regions PR1 and PR2 between the semiconductor chips 110a and 110b and 130a and 130b. The plurality of inflection points PI1A, PH1B may be formed in the horizontal direction, for example, the X direction of the substrate 102-2.

The substrate 102-2 may include the curved faces CP1A and CP1B and CP2A and CP2B corresponding to the curved surfaces CF in the curved surface region 150CR-4 of the curved surface type heat spreader 150-4. When the curved surface type heat spreader 150-4 is a bulged type having the surface 150a bulging upward, the substrate 102-2 may be a bulged type having the front surface 102a or the rear surface 102b bulging upward.

On the surfaces of the semiconductor chips 110a and 110b and 130a and 130b, there is no air layer formed between the TIM layers 170 and the curved surface type heat spreader 150-4, and the thickness of the TIM layer 170 on the semiconductor chips 110a and 110b and 130a and 130b is entirely same, thus, a heat radiation efficiency may increase.

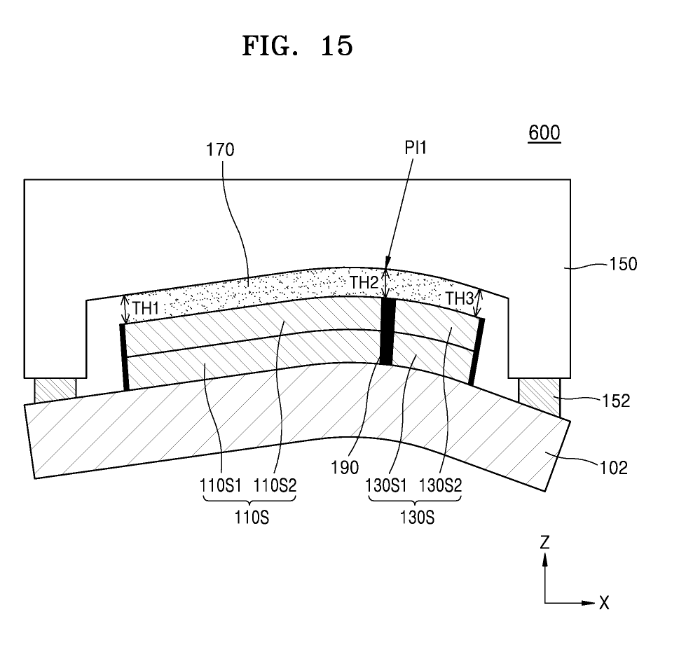

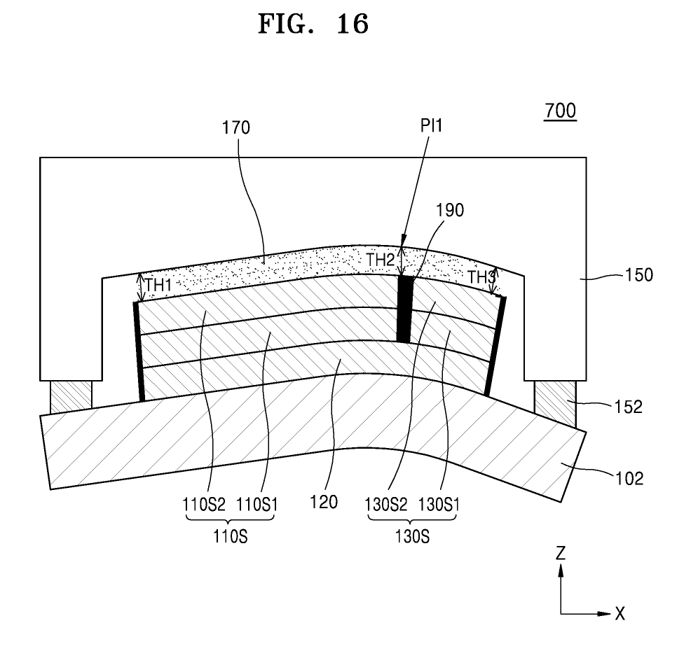

FIGS. 15 and 16 are cross-sectional views respectively illustrating a semiconductor package 600 according to an aspect of the present inventive concept.

In one embodiment, the semiconductor package 600 is almost the same as the semiconductor package 100 in FIGS. 1 through 4 except for first and second semiconductor chip stacks 110S and 130S mounted on the substrate 102. A semiconductor package 700 in FIG. 16 is almost the same as with the semiconductor package 600 in FIG. 15 except for the first and second semiconductor chip stacks 110S and 130S mounted on an interposer chip 120 on the substrate 102. In FIGS. 15 and 16, reference numerals the same as those of FIGS. 1 through 4 are used to represent the same components. In FIGS. 15 and 16, explanations overlapping with those of FIGS. 1 through 4 are briefly described or omitted.

The semiconductor package 600 may include a plurality of semiconductor chip stacks, for example, two semiconductor chip stacks, such as, first and second semiconductor chip stacks 110S and 130S, on the substrate 102, the TIM layer 170 on the first and second semiconductor chip stacks 110S and 130S, and the curved surface type heat spreader 150 located on the TIM layer 170.

The semiconductor package 700 may include an interposer chip 120 on the substrate 102, a plurality of semiconductor chip stacks, for example, the first and second semiconductor chip stacks 110S and 130S on the interposer chip 120, the TIM layer 170 located on the first and second semiconductor chip stacks 110S and 130S, and the curved surface type heat spreader 150 located on the TIM layer 170. The interposer chip 120 is provided to facilitate electric connections between the first and second semiconductor chip stacks 110S and 130S and the substrate 102.

The first semiconductor chip stack 110S may include two sub semiconductor chips, for example, first and second sub semiconductor chips 110S1 and 110S2. The first and second sub semiconductor chips 110S1 and 110S2 may be the same as the chips explained in connection with the first semiconductor chip 110 described above. A second semiconductor chip stack 130S may include two sub semiconductor chips 130S1 and 130S2.

The two sub semiconductor chips 130S1 and 130S2 may be chips the same as the semiconductor chip 130 described above. Even though the first semiconductor chip stack 110S includes the two sub semiconductor chips 110S1 and 110S2 in FIG. 15, in another embodiment, the first semiconductor chip stack 110S may be a single semiconductor chip 110 as described above, while the second semiconductor chip stack 130S includes a plurality of chips. Though two semiconductor chips are described herein as being part of the chip stacks, each chip stack can have more than two semiconductor chips.

The TIM layer 170 may be entirely attached on upper surfaces of the first and second semiconductor chip stacks 110S and 130S. The adhesion thicknesses TH1 and TH3 of the TIM layer 170 on edges of the first and second semiconductor chip stacks 110S and 130S may be the same as the adhesion thickness TH2 of the TIM layer 170 on a portion between the first and second semiconductor chip stacks 110S and 130S. The TIM layer 170 may easily radiate heat generated from the first and second semiconductor chip stacks 110S and 130S when attached on the curved surface type heat spreader 150 in a uniform thickness on the first and second semiconductor chip stacks 110S and 130S.

While the inventive concept has been particularly shown and described with reference to embodiments thereof, it will be understood that various changes in form and details may be made therein without departing from the spirit and scope of the following claims.

What is claimed is:

1. A semiconductor package, comprising:
a package substrate having a front surface and a rear surface;
a plurality of semiconductor chips including at least a first semiconductor chip and a second semiconductor chip separately located to be horizontally adjacent to each other on the front surface of the package substrate;
a thermal interface material layer located on the plurality of semiconductor chips; and
a curved surface type heat spreader located on the thermal interface material layer, wherein the thermal interface material layer is between the curved surface type heat spreader and the plurality of semiconductor chips, and wherein a surface of the curved surface type heat spreader has a curved surface region comprising a curved surface having an inflection point corresponding to a vicinity region between the first semiconductor chip and the second semiconductor chip.

2. The semiconductor package according to claim 1, wherein
the inflection point of the curved surface type heat spreader is a point at which a slope of the curved surface changes from a positive value into a negative value with respect to the front surface of the package substrate.

3. The semiconductor package according to claim 1, wherein
the inflection point of the curved surface type heat spreader is a point at which the slope of the curved surface changes from a negative value to a positive value with respect to the front surface of the package substrate.

4. The semiconductor package according to claim 1, wherein
another surface of the curved surface type heat spreader opposite the curved surface is a flat surface.

5. The semiconductor package according to claim 1, wherein
the package substrate comprises a curved face corresponding to the curved surface in the curved surface region of the curved surface type heat spreader.

6. The semiconductor package according to claim 5, wherein
the curved surface type heat spreader is a bulged type having the curved surface bulging upward, and the package substrate is a bulged type having the front surface bulging upward.

7. The semiconductor package according to claim 5, wherein
the curved surface type heat spreader is a bulged type having the curved surface bulging downward, and the package substrate is a bulged type having the front surface bulging downward.

8. The semiconductor package according to claim 1, wherein
the curved surface type heat spreader further comprises step structures which correspond to two ends of the semiconductor chips and are connected to the curved surface region.

9. The semiconductor package according to claim 1, wherein
the curved surface type heat spreader comprises a plurality of curved surface regions and an inflection point is located on each of the curved surface regions.

10. The semiconductor package according to claim 1, wherein
each of the first and second semiconductor chips is either a single semiconductor chip not part of a semiconductor chip stack, or is part of a semiconductor chip stack.

11. The semiconductor package according to claim 1, wherein
an air layer is not formed on the plurality of semiconductor chips between the thermal interface material layer and the curved surface type heat spreader.

12. A semiconductor package, comprising:
a package substrate;
a plurality of semiconductor chips including a first semiconductor chip horizontally adjacent to a second semiconductor chip on the package substrate;
a thermal interface material layer located on and entirely attached on the semiconductor chips; and
a curved surface type heat spreader,
wherein the curved surface type heat spreader contacts an entire upper surface of the thermal interface material layer, and has a contact face that contacts the upper surface of the thermal interface material layer that has a curved surface region comprising a curved surface having an inflection point corresponding to a vicinity region between the first semiconductor chip and second semiconductor chip.

13. The semiconductor package according to claim 12, wherein
an air layer is not formed on the plurality of semiconductor chips between the thermal interface material layer and the curved surface type heat spreader, and an adhesion thickness of the thermal interface material layer corresponding to edges of the semiconductor chips is the same as an adhesion thickness of the thermal interface material layer corresponding to a portion between the semiconductor chips.

14. The semiconductor package according to claim 12, wherein
the inflection point of the curved surface type heat spreader is a point at which a slope of the contact surface changes from a negative value to a positive value with respect to a front surface of the package substrate, or a point at which the slope of the contact surface changes from the positive value to the negative value with respect to the front surface of the package substrate.

15. The semiconductor package according to claim 12, wherein
the curved surface type heat spreader further comprises a non-contact face which is connected to the contact face and does not contact the thermal interface material layer.

16. The semiconductor package according to claim 12, wherein
the substrate comprises a curved face with respect to the curved surface type heat spreader.

17. The semiconductor package according to claim 12, wherein the thermal interface material layer is formed of a hardened material having a better heat conductivity than air.

18. A semiconductor package, comprising:
a package substrate having a front surface and a rear surface;
a plurality of semiconductor chips including at least a first semiconductor chip and a second semiconductor chip separately located to be horizontally adjacent to each other on the front surface of the package substrate;
a thermal interface material layer located on the plurality of semiconductor chips and located on a molding layer formed between the first semiconductor chip and the second semiconductor chip; and
a curved surface type heat spreader located on the thermal interface material layer, wherein the thermal interface material layer is between the curved surface type heat spreader and the plurality of semiconductor chips, and is between the curved surface type heat spreader and the molding layer, and wherein a surface of the curved surface type heat spreader has a curved surface region comprising a curved surface having an inflection point corresponding to a vicinity region between the first semiconductor chip and the second semiconductor chip where the molding layer is located.

19. The semiconductor package according to claim 18, wherein
another surface of the curved surface type heat spreader opposite the curved surface is a flat surface.

20. The semiconductor package according to claim 18, wherein
the package substrate comprises a curved face with respect to the curved surface type heat spreader.
